(19) United States
(12) Patent Application Publication
(10) Pub. No.: US 2025/0310006 A1
(43) Pub. Date: Oct. 2, 2025

(54) ANALYSIS AND MEASUREMENT OF SIGNALS IN A MULTI-CHANNEL ANTENNA RECEIVER WITH MULTI-CHANNEL ANALOG-DIGITAL CONVERTERS (ADCS)

(71) Applicant: VIAVI SOLUTIONS INC., Chandler, AZ (US)

(72) Inventors: Bon-Jin KU, Seoul (KR); Chang-Hyun PARK, Goyang-si (KR); Seung-Gon HONG, Incheon (KR)

(73) Assignee: VIAVI SOLUTIONS INC., Chandler, AZ (US)

(21) Appl. No.: 18/616,742

(22) Filed: Mar. 26, 2024

(51) Int. Cl. H04B 17/00; G01R 23/18; H04B 17/10

(52) U.S. Cl. CPC H04B 17/0085; G01R 23/18; H04B 17/101

(57) ABSTRACT

A test device such as a spectrum analyzer includes a multi-channel analog-digital converter (ADC) subsystem and a multi-channel antenna receiver. When a user wants to analyze a particular signal coming from a particular antenna in more detail, the signal path is routed through a divider to put the same signal into the inputs of two or more ADC channels. Digital output signals of the selected ADC channels are combined through averaging in cascaded layers, altogether, or in another configuration, enhancing signal-to-noise ratio (SNR) and noise spectral density (NSD) of the overall output signal, which may be used for further processing and/or analysis. The selected RF signal may be directed from multiple antennas to the ADC channel inputs allowing further increase of input signal levels.

### TECHNICAL FIELD

This patent application is directed to spectrum analyzers, and more specifically, a multi-channel antenna spectrum analyzer with multi-channel analog-digital converters (ADCs) for measurement and analysis of radiofrequency (RF) signals.

### BACKGROUND

A cell site, also known as a cell tower or cellular base station, includes an antenna and electronic communications equipment to support cellular mobile device communication. The antenna and equipment are typically placed in connection with a radio mast or tower, and the equipment generally connects cell site air interfaces to wireline networks, which may be comprised of fiber optic cables and coaxial cables. When setting up or maintaining a cell site, technicians use, among other test devices, spectrum analyzers, typically portable spectrum analyzers, to test signal strength, frequency, phase, interference, etc.

At a cell site, there may be a variety of signals depending on technology, e.g., 4G Long Term Evolution (LTE), 5G New Radio (NR), Dynamic Spectrum Sharing (DSS), etc. Additionally, other signals such as Citizens Broadband Radio Service (CBRS) and similar communication signals may also be present and potentially interfere with the cellular network signals. Configuring instruments to evaluate the RF performance of the channel under test in these environments where channels are dynamically assigned at different locations may be a time-consuming process for RF engineers. Furthermore, depending on the configuration of the spectrum analyzer, accurate analysis of detected signals may be a challenge.

### BRIEF DESCRIPTION OF DRAWINGS

Features of the present disclosure are illustrated by way of example and not limited in the following Figure(s), in which like numerals indicate like elements, in which:

FIG. 1 illustrates a diagram of a test device in a test environment, according to an example.

FIG. 2 illustrates a block diagram of major components of the test device including a multi-channel ADC subsystem, which may be used to measure and analyze RF signals received through a multi-channel antenna receiver, according to an example.

FIG. 3 illustrates a diagram of the multi-channel ADC subsystem, according to an example.

FIGS. 4A and 4B illustrate a block diagram of a spectrum analyzer with a multi-channel antenna receiver and a multi-channel ADC subsystem to measure and analyze RF signals, according to an example.

FIG. 4C illustrates different configurations of ADC output signal averaging, according to examples.

FIG. 5 illustrates a flow chart of a method for employing a spectrum analyzer with a multi-channel ADC subsystem to measure and analyze RF signals received through a multi-channel antenna receiver, according to an example.

FIG. 6 illustrates a block diagram of the test device, according to an example.

### DETAILED DESCRIPTION

For simplicity and illustrative purposes, the present disclosure is described by referring mainly to examples and embodiments thereof. In the following description, numerous specific details are set forth in order to provide a thorough understanding of the present disclosure. It will be readily apparent, however, that the present disclosure may be practiced without limitation to these specific details. In other instances, some methods and structures readily understood by one of ordinary skill in the art have not been described in detail so as not to unnecessarily obscure the present disclosure. As used herein, the terms “a” and “an” are intended to denote at least one of a particular element, the term “includes” means includes but not limited to, the term “including” means including but not limited to, and the term “based on” means based at least in part on.

Modern signal processing applications require ADCs with wide dynamic range, high bandwidth, low distortion, and low noise. As well as having traditional DC specifications (offset error, gain error, differential linearity error, and integral linearity error), sampling ADCs (ADCs with an internal sample-and-hold function) are generally specified in terms of Signal-to-Noise Ratio (SNR), Signal-to-Noise-Plus Distortion Ratio [S/(N+D), or SINAD], Effective Number of Bits (ENOB), Harmonic Distortion, Total Harmonic Distortion (THD), Total Harmonic Distortion Plus Noise (THD+N), Intermodulation Distortion (IMD), and Spurious Free Dynamic Range (SFDR).

While ADCs for spectrum analyzers may be selected with optimal values for some or all of the performance parameters discussed above, increasingly higher carrier frequencies and higher bandwidths (higher data throughput) of cellular communication signals make measurement and analysis of such signals susceptible to noise. High-speed ADCs tend to have lower SNRs compared to lower speed versions. Furthermore, when performing test and analysis for cell site equipment RF technicians may need spectrum analyzers and similar test devices that can process multiple input signals with different frequencies, bandwidths, and types. For example, one signal may be a cellular network signal in GHz frequency range and broad bandwidth, while another signal may be a lower frequency (e.g., MHz range), low bandwidth signal. A technician may want to focus on one of those signals and analyze it further. When a single multi-channel ADC is used to convert the input signals to digital signals, the ADC's performance characteristics may not allow optimum performance for all input signals. For example, a signal-to-noise ratio (SNR) of the ADC may be sufficiently high for a high frequency, narrow bandwidth signal (e.g., 2.4 GHz, 25 MHz), but unacceptable for a low frequency, high bandwidth signal (e.g., 300 MHz, 100 MHz) provided to the ADC at the same time. Thus, high performance functions with various frequency and various bandwidths for 6 GHz (and above) may be a challenge in spectrum analyzers.

In some examples of the present disclosure, a test device such as a spectrum analyzer may include a multi-channel ADC subsystem and a multi-channel antenna receiver, that is a receiver with multiple input antennas. Such a multi-channel ADC may receive different RF signals through antennas connected to each channel. When a user wants to analyze a particular signal coming from a particular antenna in more detail, the signal path may be routed through a divider to put the same signal into the input of two or more ADC channels. Digital output signals of the selected ADC channels may be averaged in cascaded layers, altogether, or in another configuration, enhancing signal-to-noise ratio (SNR) and noise spectral density (NSD) of the overall output signal, which may be used for further processing and/or analysis. The selected RF signal may be directed from one or more antennas to the ADC channel inputs allowing further increase of input signal levels in some examples.

Some advantages and benefits of the systems and methods described herein are readily apparent. For example, high-speed sampling ADCs may be used with enhanced SNR and NSD parameters through the use of multiple ADC channels and averaging of the digital output signals. Signal levels may be further enhanced by directing input RF signals from multiple antennas to the selected ADC channel inputs. Resulting accurate testing and analysis of network signals and any interfering signals, in turn, may improve overall performance of a communications network. Other benefits and advantages may also be apparent.

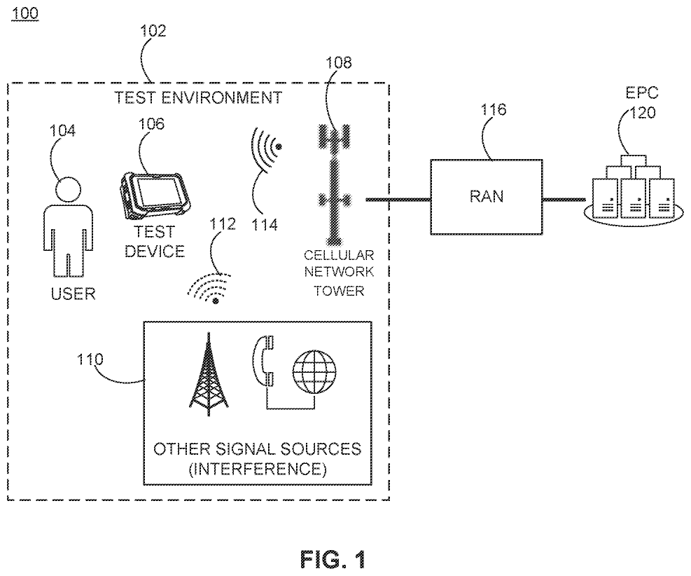

FIG. 1 illustrates a diagram 100 of a test device 106 in a test environment 102, according to an example. As shown in the diagram 100, a user 104 may use a test device 106 to test and analyze signals 114 from a cellular network tower 108, as well as other signals 112, which may come from other signal sources 110 such as a radio tower, telecom signals, and others, which may interfere with the signals 114 from the cellular network tower 108. The cellular network tower 108 may be part of a cell site and connected to backhaul via a radio access network (RAN) 116 and the backhaul may connect to Evolved Packet Core (EPC) 120.

A connection between the cellular network tower 108 and the rest of the world may be referred to as a backhaul link or simply backhaul. A backhaul may include wired, fiber optic and wireless components, such as microwave transmission equipment. In conventional 3G and 4G architectures, fronthaul is associated with a RAN 116 architecture including centralized base band units (BBUs), i.e., baseband controllers, and standalone remote radio heads (RRHs) installed at remote cell sites. These BBU and RRH functional blocks, as well as the equipment that performs these functions, are located further away from each other than in prior mobile backhaul models. In some instances, the RRH and BBU are at the same location. In other instances, the RRH is located at the cell site, whereas the BBU is located in a centralized and protected location where it serves multiple RRHs. The optical links that interconnect the BBU and the multiple RRHs are referred to as fronthaul. The fronthaul includes interfaces between the RRH and the BBU. The backhaul includes interfaces between the BBU and the EPC 120.

In an example, the test environment 102 may include the cell site, which includes the cellular network tower 108 or cellular base station having antennas and electronic communications equipment to support cellular mobile device communication. The antennas and equipment are typically placed in connection with a radio mast or tower, and the equipment generally connects cell site air interfaces to wireline networks, which may be include fiber optic cables and coaxial cables. Typically, the cell site may be connected to backhaul via the RAN 116 and the backhaul may connect to the EPC 120.

The RAN is the part of a mobile network that connects end-user devices, like smartphones, to the cloud. This is achieved by sending information via radio waves from end-user devices to a RAN's transceivers, and finally from the transceivers to the core network which connects to the global internet. Diagram 100 shows the test device 106 performing signal analysis. In an example, the user 104, such as a cellular service provider technician, may use the test device 106 to perform signal analysis for discovered carrier frequency and technology as well as discovered channels of selected technologies. Furthermore, interference hunting and beam centric electromagnetic field (EMF) testing on a selected carrier may be performed with the test device 106. In an example use case, the testing may be performed when the cell site is being installed, such as to ensure proper operation of the cell site with user devices, such as smartphones or other end user cellular devices. In another example use case, after installation, customers of the cellular service provider may be having technical issues, and the user 104 may use the test device 106 to check for signal interference from the other signal sources 110 or other potential causes of the technical issues so the technical issues can be resolved.

As discussed above, the test device 106 may be operable to perform an analysis on selected channels (by the user 104 or automatically). Carrier frequencies of available channels for one or more technologies may also be detected automatically or by the user 104. The carrier frequencies may be a center frequency and/or a synchronization signal block (SSB) frequency depending on the technology. The technologies may include, but are not limited to, 4G LTE, 5G NR, and DSS. Additional examples of the technologies may include LTE-FDD, LTE-TDD, NR, DSS-FDD, DSS-TDD where FDD is frequency division duplex and TDD is time division duplex.

Accurate testing and analysis of network signals and any interfering signals may improve overall performance of a communications network. However, supporting high performance functions with various frequency and bandwidths, especially at and above 6 GHz, may be a challenge for spectrum analyzers. While analysis of various signals involves a number of components and their respective performance characteristics in the test device 106, ADC performance may be a substantial contributor to accurate analysis or lack thereof. In some examples, multiple ADCs and RF antenna paths may be provided in the test device 106 and the ability to analyze a selected RF signal through multiple ADC channels and averaging of output signals for the task, thus increasing an overall efficiency and performance of the spectrum analyzer (test device 106).

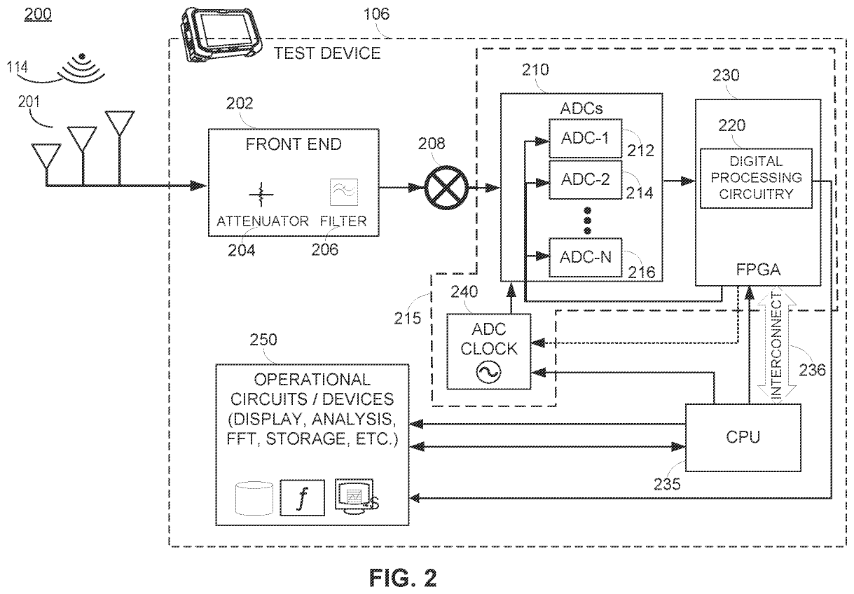

FIG. 2 illustrates a block diagram 200 of major components of the test device 106 including a multi-channel ADC subsystem 215, which may be used to measure and analyze RF signals received through a multi-channel antenna receiver, according to an example. As block diagram 200 shows, the signals 114 (e.g., from the cellular network tower 108) may be input to the test device 106 through a plurality of antennas 201 and pre-processed by a front end 202. The front end 202 may include, among other circuits and subsystems, an attenuator 204 and a filter 206. The attenuated and filtered signal (pre-processed RF signal) may be down-converted at a mixer 208, and the down-converted signal provided to ADCs 210 of the multi-channel ADC subsystem 215. The multi-channel ADC subsystem 215 may include any number of multi-channel ADCs 210, such as ADC-1 212, ADC-2, 214, to ADC-N 216, the field programmable gate array (FPGA) 230, and an ADC sample clock 240. The ADCs 210 may receive one or more clock signals from the ADC sample clock 240 to sample the input signal(s) and convert them to digital outputs. A CPU 235 may manage one or more components of the test device 106 such as ADC sample clock 240, FPGA 230, and at least some of the operational circuits and devices 250 (also referred to as operational subsystems).

In some examples, the multi-channel ADC subsystem 215 may be managed, that is, suitable ADCs selected for analog-digital conversion of input signals, by the FPGA 230. Digital output of the selected ADCs may be provided to digital processing circuitry 220, which may be partially or wholly implemented in the FPGA 230. The digital processing circuitry 220 may include detectors, normalizers, filters, etc. Digitally processed signals may be provided by the multi-channel ADC subsystem 215 to operational circuits and devices 250, which may perform analytical operations such as displaying the signals, fast Fourier transforms (FFTs), storing the signals and/or analysis results, and similar operations. Thus, the operational circuits and devices 250 may include an analysis subsystem, a display subsystem, an FFT subsystem, a storage subsystem, and comparable subsystems and circuits.

In some examples, the CPU 235 may communicate with other components over various interfaces and control their operations. For example, the CPU 235 may control the ADC sample clock 240 and set clock frequencies to be provided to selected ADCs. The ADC sample clock 240 may alternatively be controlled by the FPGA 230. The CPU 235 and the FPGA 230 may also communicate over a peripheral component interconnect (PCI) interface (interconnect 236). For example, processed (spectrum-analyzed) data may be transmitted by the FPGA 230 to the CPU 235 to be further processed and/or displayed.

As mentioned herein, the test device 106 may be a spectrum analyzer (for example, a portable spectrum analyzer to be used in the field) and may include additional circuitry and subsystems such as a voltage-controlled oscillator (VCO) for the mixer 208, additional filters, mixers, oscillators, a frequency synthesizer, and so on. Thus, the analog input signal(s) may be processed by any number of analog processing circuitry and the digital signals converted by the multi-channel ADC subsystem 215 may be processed by any number of digital processing circuitry.

In some examples, the test device 106 may receive different RF signals through the antennas 201. In a default configuration, each antenna may be connected to a corresponding ADC channel for digitization of different signals. When a user wants to analyze a particular signal coming through a particular antenna in more detail, the signal path may be routed through a divider to put the same signal into the input of two or more ADC channels. Digital output signals of the selected ADC channels may be averaged in cascaded layers, altogether, or in another configuration, enhancing signal-to-noise ratio (SNR) and noise spectral density (NSD) of the overall output signal, which may be used for further processing and/or analysis. NSD refers to power spectral density of noise or the noise power per unit of bandwidth. In other examples, the selected RF signal may be directed through multiple antennas to the ADC channel inputs allowing further increase of input signal levels in some examples.

It should be appreciated that FIG. 2 shows a simplified block diagram of major components of the test device 106. A test device such as a spectrum analyzer may be implemented with additional of fewer components, where certain functionality may be distributed among various components and sub-systems or performed by additional components or sub-systems. Furthermore, the test device 106 may be any RF test device including, but not limited to, a spectrum analyzer, a cellular system monitoring device, an RF power analyzer, etc.

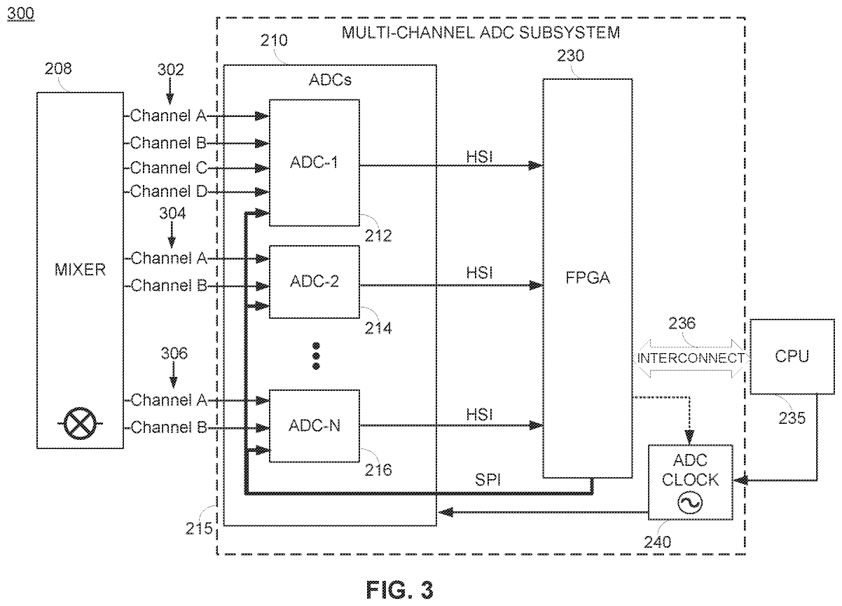

FIG. 3 illustrates a diagram 300 of the multi-channel ADC subsystem 215 managed by the FPGA 230, according to an example. The multi-channel ADC subsystem 215 and its components may be used with similar components shown in FIG. 2. As shown in diagram 300, multiple input signals may be received at a multiple channel test device (spectrum analyzer) and corresponding down-converted signals may be forwarded by the mixer 208 to one or more ADCs 210 in the multi-channel ADC subsystem 215. For example, four inputs may be forwarded as channels A, B, C, and D (302) to ADC-1 212; two inputs may be forwarded as channels A and B (304 or 306) to either ADC-2 214 or ADC-N 216.

Diagram 300 further shows CPU 235 communicatively coupled to the FPGA 230 through the PCI interface (interconnect 236) and connected to the ADC sample clock 240 to control clock frequencies provided to the selected ADCs. The ADC sample clock 240 may alternatively be controlled by the FPGA 230. Digitized IF signals from the ADCs 210 may be provided to the FPGA 230 over a high-speed data transfer interface (HSI). For example, the HSI may be a standard interface according to Joint Electronic Device Engineering Council “JEDEC” standard JESD204B/C. The transferred data may be processed and/or stored by the FPGA 230. The FPGA 230 may control (e.g., select, activate) ADCs through a lower bandwidth interface such as a serial peripheral interface (SPI), which is a synchronous serial communication interface used for short-distance communication, primarily in embedded systems.

In some examples, the mixer 208 may down-convert and provide one input signal at a time to the ADCs 210. Thus, multiple input signals may be processed serially with time multiplexing. In other examples, the mixer 208 may be a mixing subsystem and include two or more mixers, which may down-convert multiple RF signals to IF signals simultaneously. Thus, multiple IF signals may be provided to one or more ADCs in parallel. Digitized signals from the ADCs may be provided, as mentioned herein, through the HIS to various input ports of the FPGA 230. If the FPGA 230 does not have sufficient number of input ports, a multiplexer (not shown) may be used between the ADCs 210 and the FPGA 230.

A non-exhaustive example list of RF signals may include a 2195 MHz signal (with a bandwidth of 800 MHz), a 1200 MHz signal (with a bandwidth of 400 MHz), a 370 MHz signal (with a bandwidth of 200 MHz), and a 185 MHz signal (with a bandwidth of 100 MHz), for example.

The FPGA 230 may select suitable ADC(s) within available ADCs 210. As mentioned above, multiple input signals may be received at a multiple channel test device (spectrum analyzer) with different frequencies and bandwidths. The signals may also be of different type (also referred to as technology) such as time division multiplexed, frequency division multiplexed, etc. Multi-channel ADCs typically convert each input channel sequentially using an input multiplexer. Certain applications may require simultaneous conversions, especially when phase information exists between different channels. For example, wireless applications may need I and Q channels to be converted at the same instance. In such scenarios, multiple ADCs and parallel conversions on each channel may be used. Alternatively, simultaneous sampling ADCs may perform simultaneous conversion using multiple track-and-hold (T/H) paths to sample the inputs at the same instant, then perform the conversion for each channel.

As mentioned herein, increasingly higher frequencies and wider bandwidths of network signals to be analyzed require higher speed sampling ADCs. However, high-speed ADCs commonly have the disadvantage of lower SNRs. A multi-antenna, multi-channel ADC test device as described herein may overcome that disadvantage by directing an RF signal of interest to multiple ADC channels and averaging output signals of the ADC channels, thereby improving overall SNR for the system.

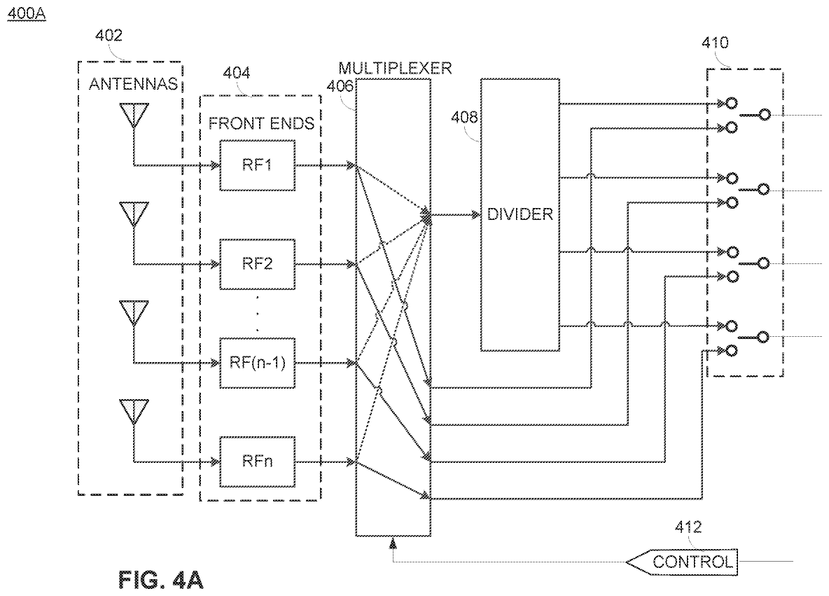

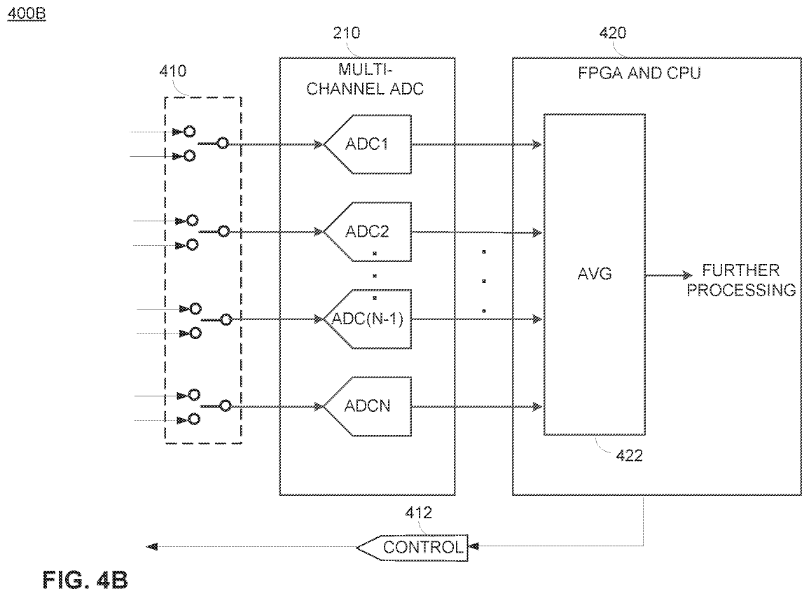

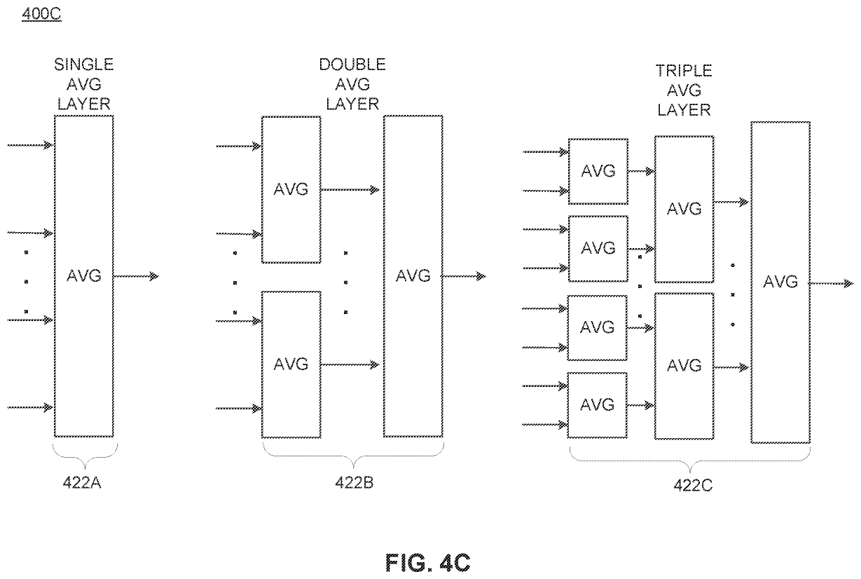

FIGS. 4A and 4B illustrate a block diagram of a spectrum analyzer with a multi-channel antenna receiver and a multi-channel ADC subsystem to measure and analyze RF signals, according to an example. As shown in a diagram 400A of FIG. 4A, antennas 402 of the spectrum analyzer may be used to receive multiple RF signals. For example, each antenna may be tuned to a particular frequency band in order to efficiently receive RF signals in that frequency band. Each antenna may be coupled to a corresponding front end within front ends 404 of the spectrum analyzer. The front ends 404 may perform functions such as amplification, filtering, attenuation, etc. as described previously. In a default operation, each of the RF signal paths may be connected (through a down-converter-not shown) to an input of a ADC channel of a multi-channel ADC 210 of the spectrum analyzer.

In some examples, a multiplexer 406 may direct RF signals from different paths (front ends or antennas) to a divider 408 or to the corresponding inputs of the ADC channels as discussed above. The multiplexer 406 may be controlled (412) by an FPGA or a CPU of the spectrum analyzer. The divider 408 may divide and directed received RF signal(s) to multiple ADC channel inputs allowing the same RF signal to be digitized by multiple ADC channels simultaneously.

In some examples, a single RF signal through one of the antennas 402 may be the signal of interest and directed to the divider 408 by the multiplexer 406. In other examples, the RF signal of interest may be directed through multiple antennas (and front ends) to the divider 408 by the multiplexer 406. While some of the antennas may not be efficient for the RF signal of interest (frequency band mismatch), still the combination of the received RF signal from multiple antennas may increase its signal level allowing further enhancement of SNR.

An optional set of switches 410 may allow the multi-channel ADC 210 to receive individual RF signals per the default operation or the RF signal of interest from the divider 408. A diagram 400B of FIG. 4B shows the selected signals being provided to inputs of the ADC channels of the multi-channel ADC 210, and the digitized output signals of the ADC channels being averaged by an averaging subsystem 422 of an FPGA or CPU 420. The averaged output signal may then be used for further processing such as analysis, display, storage, etc. The FPGA or CPU 420 may also control (412) the multiplexer 406 as mentioned previously.

While not shown in the diagrams, a down-converter (mixer) may down-convert the RF signals prior to or after the multiplexer 406. Furthermore, one or more amplifiers, filters, and/or other analog signal processing elements may be used at various stages prior to the multi-channel ADC 210. The digitization of the RF signal of interest by multiple ADC channels and averaging of their output signals may improve the SNR and NSD of the spectrum analyzer. Averaging of the ADC channel output signals may be performed in a variety of ways.

FIG. 4C illustrates different configurations of ADC output signal averaging, according to examples. As shown in a diagram 400C of FIG. 4C, the averaging subsystem may be configured to combine digital output signals of the ADC channels in a variety of configurations. In one example, as shown in configuration 422A, all ADC channel output signals may be averaged together in a single averaging layer. In another example, shown in configuration 422B, a cascaded approach may be utilized, where a first layer of averaging may average output signals of subsets of the ADC channels and a second layer of averaging may then combine the averaged signals by averaging them again. In a further example, shown in configuration 422C, a triple layer cascaded approach may be used, where subsets of ADC channel output signals may be averaged in a first layer, outputs of the first layer averaged (and combined) in a second layer of averaging, and outputs of the second layer averaged (and combined in a third layer.

An example computational illustration of improvement of the SNR using multiple ADC channels and averaging is provided below. The example computation shows 3 dB improvement in SNR when two ADC channels are used. Thus, when more than two ADC channels are used and/or cascaded averaging is used, even more SNR improvement may be achieved.

$$S N {R}_{Ch . A + Ch . B} = 10 log ( \frac{{( {V}_{SignalA \_ R MS} + {V}_{SignalB \_ R MS} )}^{2}}{{( \sqrt{{( {V}_{NoiseA \_ RM S} )}^{2} + {( {V}_{NoiseB \_ R MS} )}^{2}} )}^{2}} ) = 20 log ( \frac{{V}_{SignalA \_ R MS} + {V}_{SignalB \_ R MS}}{\sqrt{{( {V}_{NoiseA \_ R MS} )}^{2} + {( {V}_{NoiseB \_ R MS} )}^{2}}} ) = 20 log ( \frac{2 \cdot {V}_{Signal \_ R MS}}{\sqrt{2 \cdot {V}_{Noise \_ R MS}^{2}}} ) = 20 log ( \frac{\sqrt{2} {V}_{Signal \_ R MS}}{{V}_{Noise \_ R MS}} ) 20 log ( \frac{{V}_{Sig \_ R MS}}{{V}_{Noise \_ RMS}} ) + 20 log ( \sqrt{2} ) = S N {R}_{ADC} + 3 dB = 20 log ( \frac{{V}_{SignalA \_ R MS} + {V}_{SignalB \_ R MS}}{\sqrt{{( {V}_{NoiseA \_ R MS} )}^{2} + {( {V}_{NoiseB \_ R MS} )}^{2}}} ) = 20 log ( \frac{2 \cdot {V}_{Signal \_ R MS}}{\sqrt{2 \cdot {V}_{Noise \_ R MS}^{2}}} ) = 20 log ( \frac{\sqrt{2} {V}_{Signal \_ R MS}}{{V}_{Noise \_ R MS}} ) 20 log ( \frac{{V}_{Sig \_ R MS}}{{V}_{Noise \_ R MS}} ) + 20 log ( \sqrt{2} ) = S N {R}_{ADC} + 3 dB$$

The example averaging configurations shown in the diagram 400C are for illustration purposes. As many practical layers of averaging may be employed as long as delays and other issues introduced by the layers can be mitigated. Furthermore, a number of ADC channels to be used and a number of channels to be combined as subsets for the first layer of averaging may be selected based on device configuration (e.g., number of ADC channels available), signal levels and frequencies, etc.

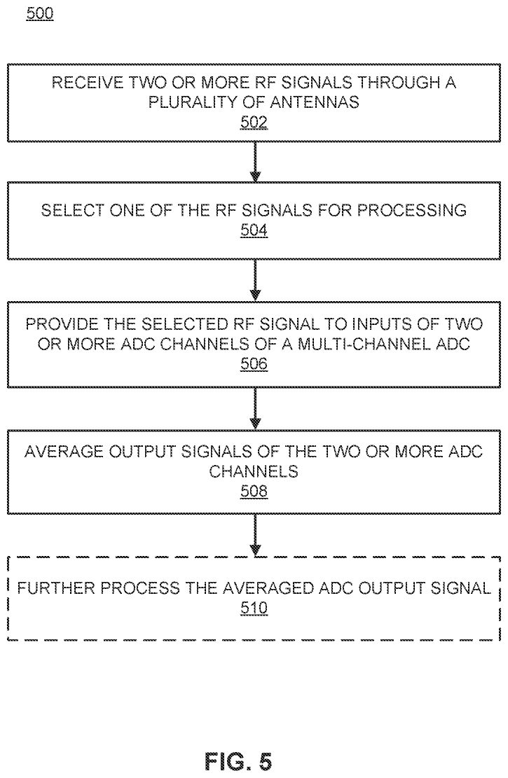

FIG. 5 illustrates a flow chart of a method 500 for employing a spectrum analyzer with a multi-channel ADC subsystem 210 to measure and analyze RF signals received through a multi-channel antenna receiver, according to an example. The method 500 is provided by way of example, as there may be a variety of ways to carry out the method described herein. Although the method 500 is primarily described as being performed by the circuits of FIGS. 4A through 4C, the method 500 may be executed or otherwise performed by one or more processing components of another system or a combination of systems. Each block shown in FIG. 5 may further represent one or more processes, methods, or subroutines, and one or more of the blocks (e.g., the selection process) may include machine readable instructions stored on a non-transitory computer readable medium and executed by a processor or other type of processing circuit to perform one or more operations described herein.

At block 502, the test device 106 may receive one or more input RF signals with different frequencies, bandwidths, and signal types (e.g., frequency division multiplexing, time division multiplexing, etc. based on a network technology) through a plurality of antennas. The input RF signals may be processed (e.g., attenuated, filtered, amplified, down-converted) at front ends corresponding to each antenna.

At block 504, one of the input RF signals may be selected for processing. For example, a user selection of an RF signal of interest may be received. The RF signal of interest may also be programmatically determined based on test environment, network environment, etc. For example, if the spectrum analyzer is being used to test a particular cellular channel, that signal may be selected as RF signal of interest by default subject to modification by the user.

At block 506, the RF signal of interest (or its down-converted and processed version) may be provided to two or more channels of a multi-channel ADC subsystem 210 of the spectrum analyzer. This may be accomplished by routing the signal path through a divider 408 to put the same signal into the inputs of the two or more ADC channels. A multiplexer 406 may be used to direct signals from different antennas to the divider and controlled by an FPGA or CPU 420 of the spectrum analyzer.

At block 508, digital output signals of the ADC channels digitizing the same RF signal of interest may be combined through averaging. The averaging may be performed by the averaging subsystem 422 in a variety of configurations. For example, all ADC channel output signals may be averaged together or subsets of ADC channel output signals may be averaged and combined in a cascaded fashion at two or more layers.

At optional block 510, the combined (averaged) digital output signals may be optionally processed by digital processing circuitry and/or received and used by operational circuits/devices 250 of the spectrum analyzer (the test device 106) to perform functions such as FFT analysis, display, storage, etc.

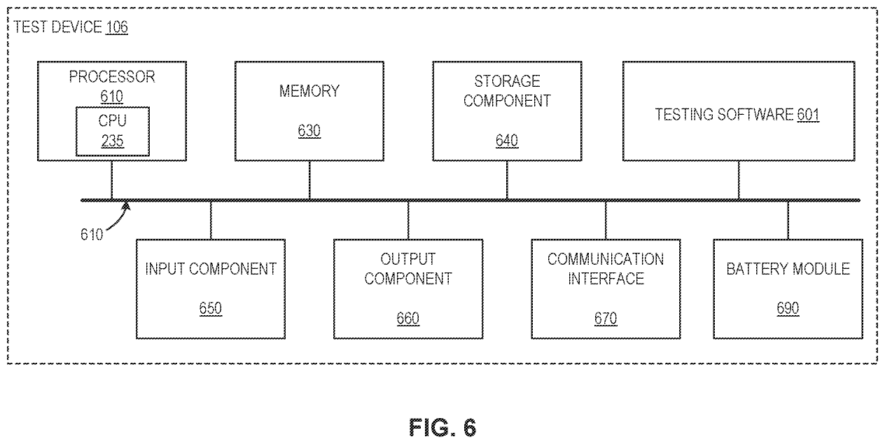

FIG. 6 illustrates a block diagram 600 of the test device 106, according to an example. As shown in block diagram 600, the test device 106 may include the components of FIG. 2 and the components shown in FIG. 6. The test device 106 may include a bus 610, a processor 620, a memory 630, a storage component 640, an input component 650, an output component 660, a communication interface 670, testing software 601, and battery module 690.

Bus 610 includes a component that permits communication among the components of test device 106. Processor 620 may be implemented in hardware, firmware, or a combination of hardware and software. Processor 620 may include one or more of a central processing unit (CPU) 235, a graphics processing unit (GPU), an accelerated processing unit (APU), a microprocessor, a microcontroller, a digital signal processor (DSP), a field-programmable gate array (FPGA), an application-specific integrated circuit (ASIC), or another type of processing component. In some examples, processor 620 may include one or more processors capable of being programmed to perform a function. Memory 630 may include one or more memories such as a random access memory (RAM), a read only memory (ROM), and/or another type of dynamic or static storage device (e.g., a flash memory, a magnetic memory, and/or an optical memory) that store information and/or instructions for use by processor 620.

Storage component 640 stores information and/or software related to the operation and use of test device 106. For example, storage component 640 may include a hard disk (e.g., a magnetic disk, solid state disk, etc.) and/or another type of non-transitory computer-readable medium.

Input component 650 may include a component that permits the test device 106 to receive information, such as via user input (e.g., a touch screen display, a keyboard, a keypad, a mouse, a button, a switch, and/or a microphone). Additionally, or alternatively, input component 650 may include a sensor for sensing information (e.g., a GPS component, an accelerometer, a gyroscope, and/or an actuator). Output component 660 includes a component that provides output information from the test device 106 (e.g., a display, a speaker, a user interface, and/or one or more light-emitting diodes (LEDs)). Output component 660 may include a display providing a GUI. Input component 650 and output component 660 may be combined into a single component, such as a touch responsive display, also known as a touchscreen.

Communication interface 670 may include a transceiver-like component (e.g., a transceiver and/or a separate receiver and transmitter) that enables test device 106 to communicate with other devices, such as via a wired connection, a wireless connection, or a combination of wired and wireless connections. Communication interface 670 may permit the test device 106 to receive information from another device and/or provide information to another device. For example, communication interface 670 may include an Ethernet interface, an optical interface, a coaxial interface, an infrared interface, an RF interface, a universal serial bus (USB) interface, a Wi-Fi interface, a cellular network interface, or the like.

Battery module 690 is connected along bus 610 to supply power to processor 620, memory 630, and internal components of the test device 106. Battery module 690 may supply power during field measurements by the test device 106. Battery module 690 may permit the test device 106 to be a portable test device.

The test device 106 may perform one or more processes described herein. The test device 106 may perform these processes by the processor 620 executing software instructions stored by a non-transitory computer-readable medium, such as memory 630 and/or storage component 640. A computer-readable medium is defined herein as a non-transitory memory device. A memory device includes memory space within a single physical storage device or memory space spread across multiple physical storage devices.

Software instructions may be read into memory 630 and/or storage component 640 from another computer-readable medium or from another device via communication interface 670. When executed, software instructions stored in memory 630 and/or storage component 640 may instruct processor 620 to perform one or more processes described herein. Additionally, or alternatively, hardwired circuitry may be used in place of or in combination with software instructions to perform one or more processes described herein. Thus, implementations described herein are not limited to any specific combination of hardware circuitry and software.

The test device 106 may include components other than shown. For example, the test device 106 may include a spectrum analyzer and power meter for performing tests described above. The number and arrangement of components shown in FIG. 6 are provided as an example. In practice, the test device 106 may include additional components, fewer components, different components, or differently arranged components than those shown in FIG. 6. Additionally, or alternatively, a set of components (e.g., one or more components) of the test device 106 may perform one or more functions described as being performed by another set of components of the test device 106.

While specific circuit configurations such as the arrangements of a number of components are shown in conjunction with the test device including a multi-channel ADC subsystem and a multi-channel antenna receiver herein, the illustrated configurations are not intended to be limiting. A test device employing multi-channels ADCs and multiple antennas to analyze an RF signal of interest may be implemented with other configurations and component values using the principles described herein.

While examples described herein are directed to configurations as shown, it should be appreciated that any of the components described or mentioned herein may be altered, changed, replaced, or modified, in size, shape, and numbers, or material, depending on application or use case, and adjusted for desired resolution or optimal measurement results.

It should be appreciated that the apparatuses, systems, and methods described herein may minimize and/or reduce analog-digital conversion errors and inaccuracies due to two or more signals with different characteristic being converted by the same ADC, and thereby facilitate more reliable and accurate RF measurements, specifically for input signals with different frequencies, bandwidths, and types. It should also be appreciated that the apparatuses, systems, and methods, as described herein, may also include, or communicate with other components not shown. For example, these may include external processors, counters, analyzers, computing devices, and other measuring devices or systems. This may also include middleware (not shown) as well. The middleware may include software hosted by one or more servers or devices. Furthermore, it should be appreciated that some of the middleware or servers may or may not be needed to achieve functionality. Other types of servers, middleware, systems, platforms, and applications not shown may also be provided at the backend to facilitate the features and functionalities of the testing and measurement system.

Moreover, single components may be provided as multiple components, and vice versa, to perform the functions and features described herein. It should be appreciated that the components of the system described herein may operate in partial or full capacity, or it may be removed entirely. It should also be appreciated that analytics and processing techniques described herein with respect to the optical measurements, for example, may also be performed partially or in full by other various components of the overall system.

It should be appreciated that data stores may also be provided to the apparatuses, systems, and methods described herein, and may include volatile and/or nonvolatile data storage that may store data and software or firmware including machine-readable instructions. The software or firmware may include subroutines or applications that perform the functions of the measurement system and/or run one or more application that utilize data from the measurement or other communicatively coupled system.

The various components, circuits, elements, components, and interfaces, may be any number of mechanical, electrical, hardware, network, or software components, circuits, elements, and interfaces that serves to facilitate communication, exchange, and analysis data between any number of or combination of equipment, protocol layers, or applications. For example, the components described herein may each include a network or communication interface to communicate with other servers, devices, components or network elements via a network or other communication protocol.

What has been described and illustrated herein are examples of the disclosure along with some variations. The terms, descriptions, and figures used herein are set forth by way of illustration only and are not meant as limitations. Many variations are possible within the scope of the disclosure, which is intended to be defined by the following claims—and their equivalents—in which all terms are meant in their broadest reasonable sense unless otherwise indicated.

1. A test device to analyze radio frequency (RF) signals, comprising:
a multi-channel receiver comprising:
a plurality of antennas to receive a plurality of RF input signals; and
a plurality of front ends coupled to the plurality of antennas to receive and pre-process the plurality of RF input signals;
a plurality of mixers to down-convert the pre-processed plurality of RF input signals;
a multiplexer to select a signal of interest among the down-converted plurality of RF input signals;
a divider to direct the selected signal of interest to a plurality of analog-digital converter (ADC) channel inputs; and
a multi-channel ADC subsystem comprising:
a plurality of ADC channels to digitize the signal of interest simultaneously; and
a field programmable gate array (FPGA) to combine digital output signals of the plurality of ADC channels through averaging.

2. The test device of claim 1, wherein the FPGA is to average the digital output signals of the plurality of multi-channel ADCs in a single layer of averaging or in multiple layers of averaging.

3. The test device of claim 2, wherein the FPGA is to average the digital output signals of the plurality of ADC channels in multiple layers of averaging by averaging two or more subsets of the digital output signals of the plurality of ADC channels in a first averaging layer, and averaging output signals of preceding averaging layers in each subsequent averaging layer.

4. The test device of claim 1, wherein the multiplexer is to provide the signal of interest from two or more of the plurality of antennas to the divider.

5. The test device of claim 1, further comprising:
one or more operational subsystems to perform analytical operations on the combined digital output signals.

6. The test device of claim 5, wherein the one or more operational subsystems include at least one of a display subsystem, an analysis subsystem, a fast Fourier transform (FFT) subsystem, or a storage subsystem.

7. The test device of claim 1, wherein the FPGA comprises one or more digital processing circuitry to receive and process the combined digital output signals.

8. The test device of claim 1, wherein the test device is a spectrum analyzer.

9. The test device of claim 1, further comprising:
a plurality of switches to select between an output of the divider and individual outputs of the plurality of front ends.

10. A test device to analyze radio frequency (RF) signals, comprising:
a multi-channel receiver comprising:
a plurality of antennas to receive a plurality of RF input signals; and
a plurality of front ends coupled to the plurality of antennas to receive and pre-process the plurality of RF input signals;
a multiplexer to select a signal of interest among the pre-processed plurality of RF input signals;
a mixer to down-convert the selected signal of interest;
a divider to direct the down-converted signal of interest to a plurality of analog-digital converter (ADC) channel inputs; and
a multi-channel ADC subsystem comprising:
a plurality of ADC channels to digitize the down-converted signal of interest simultaneously; and
a field programmable gate array (FPGA) to combine digital output signals of the plurality of ADC channels through averaging.

11. The test device of claim 10, wherein the FPGA is to average the digital output signals of the plurality of ADC channels in a single layer of averaging or in multiple layers of averaging.

12. The test device of claim 11, wherein the FPGA is to average the digital output signals of the plurality of ADC channels in multiple layers of averaging by averaging two or more subsets of the digital output signals of the plurality of ADC channels in a first averaging layer, and averaging output signals of preceding averaging layers in each subsequent averaging layer.

13. The test device of claim 10, wherein the multiplexer is to provide the signal of interest from two or more of the plurality of antennas to the mixer.

14. The test device of claim 10, further comprising:
one or more amplifiers positioned between the plurality of front ends and the multiplexer, the multiplexer and the mixer, or the mixer and the divider.

15. A method, comprising:
receiving two or more RF input signals through a plurality of antennas of a test device;
receiving a selection of one of the RF input signals as a signal of interest;
providing the signal of interest to two or more analog-digital converter (ADC) channel inputs of a multi-channel ADC subsystem of the test device;
digitizing the signal of interest simultaneously at two or more ADC channels of the multi-channel ADC subsystem; and
combining digital output signals of the two or more ADC channels by averaging the digital output signals.

16. The method of claim 15, wherein combining the digital output signals comprises:
averaging the digital output signals in a single layer of averaging or in multiple layers of averaging.

17. The method of claim 16, wherein averaging the digital output signals in multiple layers of averaging comprises:
averaging two or more subsets of the digital output signals in a first averaging layer, and averaging output signals of preceding averaging layers in each subsequent averaging layer.

18. The method of claim 15, further comprising:
providing the signal of interest from two or more of the plurality of antennas to the two or more ADC channel inputs through a divider.

19. The method of claim 15, further comprising:
combining the digital output signals at one of a field programmable gate array (FPGA) or a central processing unit (CPU) of the test device.

20. The method of claim 15, further comprising:
selecting the two or more ADC inputs from an output of a divider of the test device and individual outputs of a plurality of front ends of the test device through a plurality of switches.
